(19) United States
(12) Patent Application Publication
(10) Pub. No.: US 2026/0047051 A1
(43) Pub. Date: Feb. 12, 2026

(54) THERMAL HINGE STRUCTURE

(71) Applicant: Delta Electronics, Inc., Taoyuan City (TW)

(72) Inventors: Shih-Lin Huang, Taoyuan City (TW); Wei-Hsiang Chang, Taoyuan City (TW)

(21) Appl. No.: 19/025,032

(22) Filed: Jan. 16, 2025

(30) Foreign Application Priority Data
Aug. 12, 2024 (CN) 202421939919.2

(51) Int. Cl. H05K 7/20; G06F 1/20

(52) U.S. Cl. CPC H05K 7/20336; G06F 1/203; H05K 7/2039

(57) ABSTRACT

A thermal hinge structure is disclosed and includes a thermal conduction unit, a first heat pipe and the second heat pipe. The thermal conduction unit includes a first thermal conduction part and a second thermal conduction part. The first thermal conduction part has a first hollow part. The first hollow part is arranged along a first axis. The second thermal conduction part is rotated around the first hollow part. The first heat pipe includes a horizontal section, a bent section and an extended section. The horizontal section is disposed in the first hollow part. The bent section is connected between the horizontal section. The extended section and the extended section is thermally coupled to a heat source. The second heat pipe is disposed on the second thermal conduction part and thermally coupled to the heat source through the thermal conduction unit and the first heat pipe.

### CROSS-REFERENCE TO RELATED APPLICATION

This application claims the benefit of China Patent Application No. 202421939919.2, filed on Aug. 12, 2024. The entireties of the above-mentioned patent application are incorporated herein by reference for all purposes.

### FIELD OF THE INVENTION

The present disclosure relates to a hinge structure and more particularly to a thermal hinge structure for improving the passive heat dissipation, which is combined with a heat pipe through at least one pivot shaft to reduce the thermal resistance and temperature difference from the keyboard end to the screen end, so that an optimized thermal conduction path is formed, and the heat dissipation performance of the product is improved greatly.

### BACKGROUND OF THE INVENTION

The keyboard and the screen of the conventional notebook computers or mobile phones are mainly connected through a hinge structure to achieve folding applications. One end of the hinge structure is fixed to the base plate where the keyboard is located, another end of the hinge structure is fixed to the screen, and a pivot shaft is disposed between the two ends, so that it allows to open, close or rotate the screen relative to the base plate. In order to maintain the opening and closing rotation of the screen, the hinge structure needs to be made of materials with structural strength to provide sufficient support.

However, in addition to the keyboard, the base plate connected through the hinge structure is also provided with heat-generating devices such as a central processing unit (CPU) and a motherboard. The heat generated from the heat-generating device needs to be dissipated in time to control the temperature of the conventional notebook computers or mobile phones within a relatively stable range and ensure the normal operation of the device. Since the conventional hinge structure is limited by material for supporting strength, it is not easy to make the hinge structure with high thermal conductivity materials or incorporate the passive heat dissipation effect with the hinge structure. Therefore, the heat generated by the heat-generating device cannot be effectively transferred to the housing where the screen is located through the hinge structure for heat dissipation. As a result, the overall heat dissipation area is limited and the heat dissipation area is small. The heat dissipation effect is poor.

Therefore, there is a need of providing a thermal hinge structure for improving the passive heat dissipation, which is combined with a heat pipe through at least one pivot shaft to reduce the thermal resistance and temperature difference from the keyboard end to the screen end, so that an optimized thermal conduction path is formed, the heat dissipation performance of the product is improved greatly, and the drawbacks encountered by the prior arts are obviated.

### SUMMARY OF THE INVENTION

An object of the present disclosure is to provide a thermal hinge structure for improving the passive heat dissipation. The thermal hinge structure is combined with a heat pipe through at least one pivot shaft to reduce the thermal resistance and temperature difference from the keyboard end to the screen end, so that an optimized thermal conduction path is formed, and the heat dissipation performance of the product is improved greatly. The thermal hinge structure of the present disclosure can be combined with general hinges that provide structural support. The general hinges are placed on the left side and the right side of the notebook computers or mobile phones to provide strong support for opening or closing the screen. The thermal hinge structure can be placed between the general hinges, so that a high thermal conduction path is provided between the base plate (the heat source) and the screen. Furthermore, the thermal hinge structure of the present disclosure can also be installed independently to provide a high thermal conduction path between the base plate (the heat source) and the screen.

Another object of the present disclosure is to provide a thermal hinge structure for improving the passive heat dissipation. The thermal hinge structure can use one single pivot shaft or dual pivot shafts combined with the heat pipes to form a thermal conduction unit. One fixed part at one end is cooperated with the heat pipe, which is bent and fixed on the base plate and thermally coupled to the heat source. Another fixed part at another end is cooperated with the heat pipe, which is fixed to the screen and configured to be thermally coupled to the heat sink. The fixed parts at both ends are connected by the thermal conduction unit to form a high thermal conduction path. The thermal conductivity coefficient K is greater than 200 W/m·K, and it ensures that the heat source from the base plate is effectively conducted through the heat pipe at the base plate, the thermal conduction unit, the heat pipe at the screen or other heat distribution components. In that, the heat can be evenly distributed on the screen, and it allows the screen to achieve an even temperature effect. On the other hand, the thermal hinge structure is designed separately from the general support hinge, so as to improve the feasibility and the reliability of the thermal hinge structure. The thermal conduction unit composed of heat pipes and high thermal conductivity materials can effectively transfer and distribute the “heat source” to hinge application products, so that the power consumption of the passive cooling system can be further increased (from 12 W to 18˜30 W). Furthermore, the thermal hinge structure of the present disclosure can effectively disperse the heat source of the base plate to the screen end. It allows to take advantage of the large screen area as a heat sink to further enhance the overall system power. The thermal hinge structure can be used in mobile phones, NB, tablets, folding screens and other products.

A further object of the present disclosure is to provide a thermal hinge structure for improving the passive heat dissipation. The thermal hinge structure includes dual pivot shafts combined with heat pipes to form two parallel thermal conduction parts, and the spaced distance between each other is maintained within 15 mm. The fixed part connected to the first thermal conduction part is cooperated with the first heat pipe, and the first heat pipe is bent and fixed on the base plate and is thermally coupled to the heat source. The fixed part connected to the second thermal conduction part is fixed to the screen and cooperated with the second heat pipe, and the second heat pipe is thermally coupled to the heat sink. The first thermal conduction part and the second thermal conduction part are connected through a rotation unit, and the rotation unit allows to perform flipping movements from 0° to 360°. In addition, the thermal hinge structure is made of high thermal conductivity materials, such as copper, copper alloy, aluminum, and aluminum alloy. In this way, a high thermal conduction path from the heat source is formed through the first heat pipe, the thermal conduction unit, the second heat pipe and the screen, and the temperature difference between any two components can be maintained less than 10° C., thereby the overall passive heat dissipation effect of the system is improved sufficiently.

In accordance with an aspect of the present disclosure, a thermal hinge structure is provided. The thermal hinge structure includes a thermal conduction unit, a first heat pipe and a second heat pipe. The thermal conduction unit includes a first thermal conduction part and a second thermal conduction part. The first thermal conduction part has a first hollow part, the first hollow part is arranged along a first axis, and the second thermal conduction part is configured to rotate relative to the first hollow part around the first axis as the center. The first heat pipe includes a horizontal section, a bent section and an extended section. The horizontal section is disposed in the first hollow part, the bent section is connected between the horizontal section and the extended section, and the extended section is thermally coupled to a heat source. The second heat pipe is disposed on the second thermal conduction part and thermally coupled to the heat source through the thermal conduction unit and the first heat pipe.

In an embodiment, the thermal conduction unit further includes a protective layer disposed between the first hollow part and the first heat pipe.

In an embodiment, the first thermal conduction part is disposed on a side edge of a base plate, the extended section of the first heat pipe and the heat source are fixed on the base plate, the second thermal conduction part is connected to a screen, and the second thermal conduction part and the second heat pipe are fixed on the screen.

In an embodiment, the second thermal conduction part includes a second hollow part, the second heat pipe further includes a horizontal section, a bent section and an extended section, the bent section is connected between the horizontal section and the extended section, the horizontal section is embedded in the second hollow part, the extended section is thermally coupled to a heat sink, and the heat sink is disposed on the screen.

In an embodiment, the first heat pipe and the second heat pipe include a capillary structure, respectively, and the capillary structures are disposed on an inner wall surface of the first heat pipe and an inner wall surface of the second heat pipe.

In an embodiment, the bent section of the first heat pipe has an outer bent region and an inner bent region, and a density of the capillary structure in the inner bent region is greater than a density of the capillary structure in the outer bent region.

In an embodiment, the density of the capillary structure in the bent section is decreased linearly from the inner bent region to the outer bent region.

In an embodiment, the thermal hinge structure further includes a first fixed part connected to the first thermal conduction part and embedded in a base plate, wherein the first thermal conduction part is disposed adjacent to a side edge of the base plate, and the first fixed part, the extended section of the first heat pipe and the heat source are fixed on the base plate.

In an embodiment, the thermal hinge structure further includes a second fixed part, wherein the second fixed part is connected to the second thermal conduction part and embedded in a screen, and the second fixed part is disposed adjacent to a side edge of the screen, wherein the second thermal conduction part includes a second hollow part, the second heat pipe further includes a horizontal section, a bent section and an extended section, the bent section is connected between the horizontal section and the extended section, the horizontal section is embedded in the second hollow section, the extended section is thermally coupled to a heat sink, and the heat sink is disposed on the screen.

In accordance with another aspect of the present disclosure, a thermal hinge structure is provided. The thermal hinge structure includes a thermal conduction unit, a first heat pipe and a second heat pipe. The thermal conduction unit includes a first thermal conduction part, a rotation unit and a second thermal conduction part. The first thermal conduction part has a first hollow part, the first hollow part is arranged along a first axis, the second thermal conduction part is arranged along a second axis, the first axis and the second axis are parallel to each other, and the rotation unit is connected between the first thermal conduction part and the second thermal conduction part. The first heat pipe includes a horizontal section, a bent section and an extended section. The horizontal section is embedded in the first hollow part along the first axis, the bent section is connected between the horizontal section and the extended section, and the extended section is thermally coupled to a heat source. The second heat pipe is disposed on the second thermal conduction part and thermally coupled to the heat source through the second thermal conduction part, the rotation unit, the first conduction part and the first heat pipe.

In an embodiment, a spaced distance is formed between the first heat pipe and the second heat pipe, and the spaced distance is less than 15 mm.

In an embodiment, the thermal conduction unit further includes a protective layer disposed between the first hollow part and the first heat pipe.

In an embodiment, the thermal hinge structure further includes a first fixed part connected to the first thermal conduction part and embedded in a base plate, wherein the first thermal conduction part is disposed adjacent to a side edge of the base plate, and the first fixed part, the extended section of the first heat pipe and the heat source are fixed on the base plate.

In an embodiment, the thermal hinge structure further includes a second fixed part, wherein the second fixed part is connected to the second thermal conduction part and embedded in a screen, and the second fixed part is disposed adjacent to a side edge of the screen, wherein the second thermal conduction part includes a second hollow part, the second heat pipe further includes a horizontal section, a bent section and an extended section, the bent section is connected between the horizontal section and the extended section, the horizontal section is embedded in the second hollow section, the extended section is thermally coupled to a heat sink, and the heat sink is disposed on the screen.

In an embodiment, the rotation unit is a gear component, and the second thermal conduction part is allowed to rotate at an angle relative to the first thermal conduction part through the gear component, and the angle is ranged from 0° to 360°.

In an embodiment, the thermal conduction unit is formed by a high thermal conductivity material, and the high thermal conductivity material has a thermal conductively coefficient ranged from 200 W/m·K to 400 W/m·K.

In an embodiment, the high thermal conductivity material includes copper, copper alloys, aluminum or aluminum alloys.

In an embodiment, the thermal hinge structure further includes a structural support hinge structure, wherein the structural support hinge structure is disposed outside two opposite ends of the thermal hinge structure.

In an embodiment, the first heat pipe and the second heat pipe include a capillary structure, respectively, and the capillary structures are disposed on an inner wall surface of the first heat pipe and an inner wall surface of the second heat pipe.

In an embodiment, the bent section of the first heat pipe has an outer bent region and an inner bent region, and a density of the capillary structure in the inner bent region is greater than a density of the capillary structure in the outer bent region.

In an embodiment, the density of the capillary structure in the bent section is decreased linearly from the inner bent region to the outer bent region.

In an embodiment, a temperature difference between the heat source and the first heat pipe, a temperature difference between the first heat pipe and the first thermal conduction part, and a temperature difference between the second thermal conduction part and the second heat pipe are less than 5° C.

In an embodiment, a cross section of the first heat pipe and a cross section of the second heat pipe are a circle or a flat oblong shape, and include an internal microstructure composed of meshes, fibers, grooves or sintered powders.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural schematic diagram illustrating a thermal hinge structure according to a first embodiment of the present disclosure;

FIG. 2 shows an exemplary structure of the first hollow part connected to the first heat pipe in the present disclosure;

FIG. 3 is a structural schematic diagram illustrating a thermal hinge structure according to a second embodiment of the present disclosure;

FIGS. 4A to 4F are transverse sections illustrating examples of the internal microstructure of the heat pipe in the present disclosure; and

FIGS. 5A to 5D are longitudinal sections illustrating density change of capillary structure of the heat pipe in the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “up,” “down,” “right,” “left,” “inner,” “outer” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

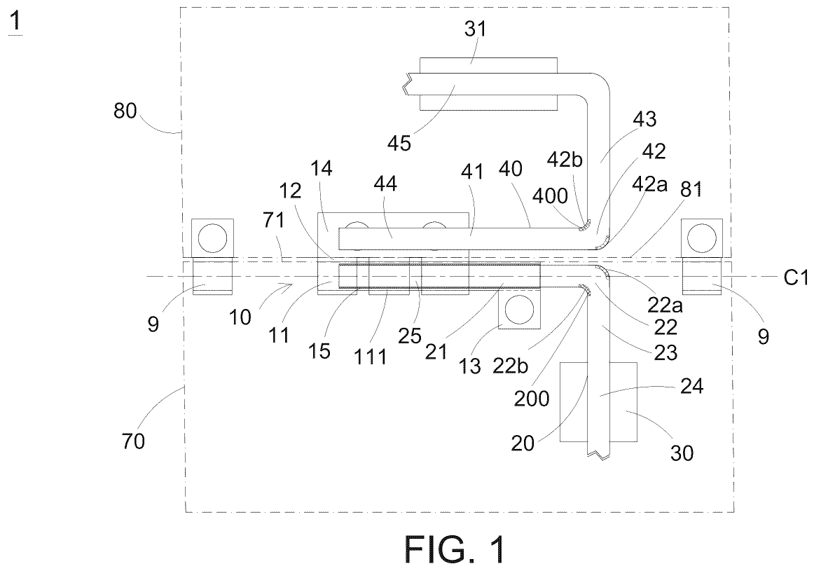

FIG. 1 is a structural schematic diagram illustrating a thermal hinge structure according to a first embodiment of the present disclosure. In the embodiment, the present disclosure provides a thermal hinge structure 1 includes a thermal conduction unit 10, a first heat pipe 20 and a second heat pipe 40. The thermal conduction unit 10 includes a first thermal conduction part 11 and a second thermal conduction part 12. The first thermal conduction part 11 has a first hollow part 111. In the embodiment, the first hollow part 111 is arranged along a first axis C1. The second thermal conduction part 12 is configured to rotate relative to the first hollow part 111 around the first axis C1 as the center. The first heat pipe 20 is embedded in the first hollow part 111 along the first axis C1. In the embodiment, the first heat pipe 20 further includes a first horizontal section 21, a first bent section 22 and a first extended section 23. The first horizontal section 21 is disposed in the first hollow part 111 along the first axis C1, the first bent section 22 is connected between the first horizontal section 21 and the first extended section 23, and the first extended section 23 is thermally coupled to a heat source 30. The second heat pipe 40 is spatially corresponding to the first heat pipe 20, disposed on the second thermal conduction part 12, and thermally coupled to the heat source 30 through the thermal conduction unit 10 and the first heat pipe 20.

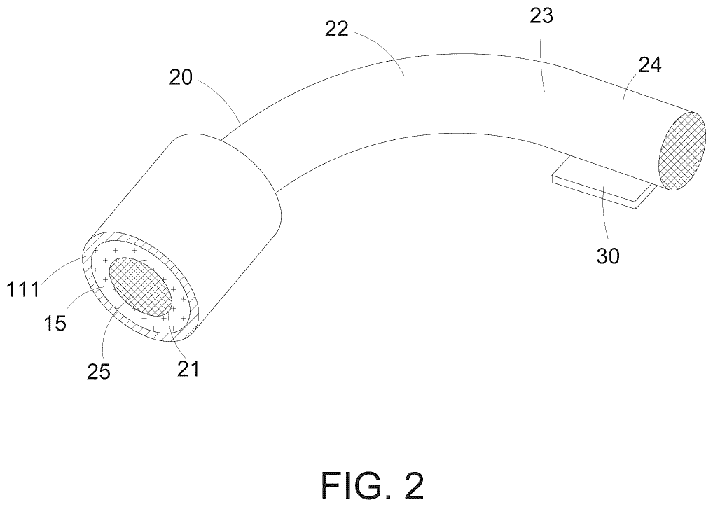

FIG. 2 shows an exemplary structure of the first hollow part connected to the first heat pipe in the present disclosure. In the embodiment, the thermal conduction unit 10 further includes a protective layer 15. The protective layer 15 is disposed between the first hollow part 111 and the first horizontal section 21 of the first heat pipe 20. Preferably but not exclusively, the protective layer 15 is made of a thermally conductive material, and the thickness of the protective layer is adjustable according to the practical requirements. The first horizontal section 21 of the first heat pipe 20 is tightly arranged in the first hollow part 111 through the protective layer 15. Certainly, the cross-sectional shapes of the first hollow part 111, the protective layer 15 and the first heat pipe 20 are adjustable according to the practical requirements, and the present disclosure is not limited thereto.

Please refer FIG. 1 and FIG. 2. In the embodiment, the first thermal conduction part 11 of the thermal conduction unit 10 is disposed on a side edge 71 of a base plate 70. Preferably but not exclusively, the base plate 70 is a base plate of laptop or mobile phone. In the embodiment, the first extended section 23 and the first bent section 22 of the first heat pipe 20 and the heat source 30 are fixed on the base plate 70. In the embodiment, the thermal hinge structure 1 further includes a first fixed part 13. The first fixed part 13 is connected to the first thermal conduction part 11 and embedded in the base plate 70, so that the first thermal conduction part 11 is disposed adjacent to the side edge 71 of the base plate 70. In other words, the first fixed part 13, the first extended section 23 and the first bent section 22 of the first heat pipe 20 and the heat source 30 are fixed on the base plate. The first thermal conducting part 11, the first fixed part 13, the first heat pipe 20 (including the first horizontal section 21, the first bent section 22 and the first extended section 23) and the heat source 30 will not rotate relative to the base plate 70. Furthermore, in the embodiment, the second thermal conduction part 12 is connected to a screen 80. Preferably but not exclusively, the screen 80 is a screen of laptop or mobile phone. Moreover, the second thermal conduction part 12 and the second heat pipe 40 are fixed on the screen. In the embodiment, the thermal hinge structure 1 further includes a second fixed part 14. The second fixed part 14 is connected to the second thermal conduction part 12 and embedded in the screen 80. Preferably but not exclusively, the second fixed part 12 is disposed adjacent to a side edge 81 of the screen 80. In the embodiment, the second heat pipe 40 further includes a second horizontal section 41, a second bent section 42 and a second extended section 43. The second horizontal section 41 is arranged parallel to the first axis C1, the second bent section 42 is connected between the second thermal conduction part 12 and the second extended section 43, and the second extended section 43 is thermally coupled to a heat sink 31. The second thermal conduction part 12, the second fixed part 14, the second heat pipe 40 and the heat sink 31 are fixed on the screen 80. Thereby, the second thermal conduction part 12, the second fixed part 14, the second heat pipe 40 and the heat sink 31 disposed on the screen 80 are allowed to rotate relative to the first thermal conduction part 11, the first fixed part 13, the first heat pipe 20 (including the first horizontal section 21, the first bent section 22 and the first extended section 23) and the heat source 30 disposed on the base plate 70 around the first axis C1 as the center. On the other hand, the heat sink 31 is thermally coupled to the heat source 30 through the second heat pipe 40, the thermal conduction unit 10 and the first heat pipe 20, so that the thermal resistance and the temperature difference between the base plate 70 and the screen 80 are reduced. Thus, the heat dissipation performance of the product is greatly improved. Preferably but not exclusively, in the embodiment, the heat sink 31 is a heat dissipation fin, a copper sheet or a graphite sheet.

In the embodiment, the thermal hinge structure 1 further includes two structural support hinge structures 9. The two structural support hinge structure 9 are disposed outside two opposite ends of the thermal hinge structure 1, respectively. In other words, the thermal hinge structure 1 of the present disclosure can be combined with the two general hinges that provide general structural support, and the two structural support hinge structures 9 are placed on the left side and the right sides of the laptop or mobile phone to provide strong support for the opening and closing rotation of the screen 80 relative to the base plate 70. Moreover, the thermal hinge structure 1 of the present disclosure is disposed between the two structural support hinge structures 9 to provide a high thermal conduction path between the base plate 70 (i.e., the heat source 30) and the screen 80. By designing the thermal hinge structure 1 and the structural support hinge structures 9 separately, the feasibility and the reliability of the thermal hinge structure 1 are improved. Certainly, the thermal hinge structure 1 of the present disclosure can also be installed independently to provide a high thermal conduction path between the base plate 70 (i.e., the heat source 30) and the screen 80, but the structural support hinge structure 9 is omitted. The present disclosure is not limited thereto.

In the embodiment, the thermal conduction unit 10 is formed by a high thermal conductivity material, and the high thermal conductivity material includes copper, copper alloys, aluminum or aluminum alloys. Preferably but not exclusively, the high thermal conductivity material has a thermal conductively coefficient ranged from 200 W/m·K to 400 W/m·K. In the embodiment, the first heat pipe 20 include a capillary structure 200 disposed on an inner wall surface of the first heat pipe 20, and the second heat pipe 40 include a capillary structure 400 disposed on an inner wall surface of the second heat pipe 40. In the embodiment, the first bent section 22 of the first heat pipe 20 has an outer bent region 22a and an inner bent region 22b. Preferably but not exclusively, the outer bent region 22a is away from the heat source 30, and the inner bent region 22b is close to the heat source 30. In the embodiment, a density of the capillary structure in the inner bent region 22b is greater than a density of the capillary structure in the outer bent region 22a. Similarly, the second bent section 42 of the second heat pipe 40 has an outer bent region 42a and an inner bent region 42b. Preferably but not exclusively, the outer bent region 42a is away from the heat sink 31, and the inner bent region 42b is close to the heat sink 31. In the embodiment, a density of the capillary structure in the inner bent region 42b is greater than a density of the capillary structure in the outer bent region 42a. Thereby, the thermal hinge structure 1 of the present disclosure uses the thermal conduction unit 10 served as the one single pivot shaft and combined with the first heat pipe 20 and the second heat pipe 40 to form an optimized thermal conduction path. The first fixed part 13 connected to the first thermal conduction part 11 is cooperated with the first heat pipe 20, which is bent and fixed on the base plate 70 and thermally coupled to the heat source 30. The second fixed part 14 connected to the second thermal conduction part 12 is cooperated with the second heat pipe 40, which is fixed to the screen 80 and configured to be thermally coupled to the heat sink 31. The first fixed part 13 and the second fixed part 14 at both ends are connected by the thermal conduction unit 10 to form a high thermal conduction path. The thermal conductivity coefficient K is greater than 200 W/m·K, and it ensures that the heat source 30 from the base plate 70 is effectively transferred to the heat sink 31 through the first heat pipe 20, the thermal conduction unit 10, the second heat pipe 40. In that, the heat can be evenly distributed on the screen 80, and it allows the screen 80 to achieve an even temperature effect.

In the embodiment, the heat is dissipated through the thermal conduction path from the heat source 30 to the heat sink 31. The place where the first heat pipe 20 contacts the heat source 30 can be defined as an evaporation end 24, and the place where the first heat pipe 20 contacts the first hollow part 111 of the first thermal conduction part 11 can be defined as a condenser end 25. In addition, the place where the second heat pipe 40 contacts the second fixed part 14 can be defined as an evaporation end 44, and the place where the second heat pipe 40 contacts the heat sink 31 can be defined as a condensation end 45. Notably, In the optimized thermal conduction path formed by the thermal hinge structure 1 of the present disclosure, the temperature difference between the heat source 30 and the evaporation end 24 of the first heat pipe 20 is less than 5° C. The temperature difference between the evaporation end 24 of the first heat pipe 20 and the condensation end 25 of the first heat pipe 20 is less than 3° C. The temperature difference between the condensation end 25 of the first heat pipe 20 and the thermal conduction unit 10 is less than 3° C. The temperature difference between the thermal conduction unit 10 and the second fixed part 14 is less than 8° C. The temperature difference from the second fixed part 14 to the evaporation end 44 of the second heat pipe 40 is less than 3° C. The temperature difference between the evaporation end 44 of the second heat pipe 40 and the condensation end 45 of the second heat pipe 40 is less than 3° C. The temperature difference between the condensation end 45 of the second heat pipe 40 and the heat sink 31 is less than 5° C. In this way, the thermal conduction unit 10 made of the high thermal conductivity material, the first heat pipe 20 and the second heat pipe 40 can effectively transfer and distribute the heat source 30 to the hinge application products, so that the power consumption of the passive cooling system can be further increased (from 12 W to 18˜30 W). Furthermore, the thermal hinge structure 1 of the present disclosure can effectively disperse the heat source 30 of the base plate 70 to the screen 80. It allows to take advantage of the large area of the screen 80 as a heat sink to further enhance the overall system power. The thermal hinge structure 1 can be used in mobile phones, NB, tablets, folding screens and other products. Certainly, the present disclosure is not limited thereto.

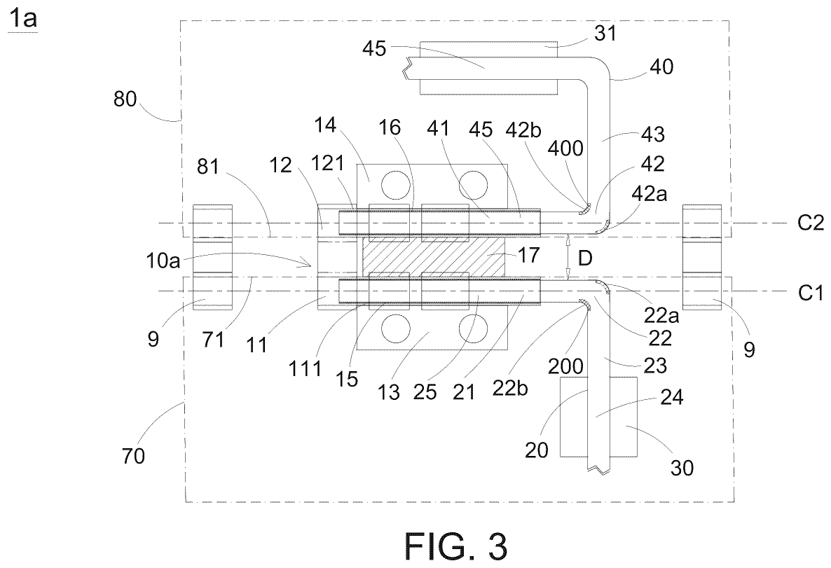

FIG. 3 is a structural schematic diagram illustrating a thermal hinge structure according to a second embodiment of the present disclosure. In the embodiment, the present disclosure provides a thermal hinge structure 1a includes a thermal conduction unit 10a, a first heat pipe 20 and a second heat pipe 40. The thermal conduction unit 10a includes a first thermal conduction part 11, a rotation unit 17 and a second thermal conduction part 12. The first thermal conduction part 11 has a first hollow part 111. In the embodiment, the first hollow part 111 is arranged along a first axis C1. The second thermal conduction part 12 is arranged along a second axis C2. The first axis C1 and the second axis C2 are parallel to each other. Preferably but not exclusively, the rotation unit 17 is a gear component and connected between the first thermal conduction part 11 and the second thermal conduction part 12. The first heat pipe 20 is embedded in the first hollow part 111 along the first axis C1. In the embodiment, the first heat pipe 20 further includes a first horizontal section 21, a first bent section 22 and a first extended section 23. The first horizontal section 21 is embedded in the first hollow part 111 along the first axis C1, the first bent section 22 is connected between the first horizontal section 21 and the first extended section 23, and the first extended section 23 is thermally coupled to a heat source 30. The rotation unit 17 is connected between the first thermal conduction part 11 and the second thermal conduction part 12. The second thermal conduction part 12 is allowed to rotate at an angle relative to the first thermal conduction part 11 through the rotation unit 17. Preferably but not exclusively, the angle is ranged from 0° to 360°. In addition, the second thermal conduction part 12 includes a second hollow part 121. The second heat pipe 40 is spatially corresponding to the first heat pipe 20, and embedded in the second hollow part 121 of the second thermal conduction part 12 along the second axis C2. In the embodiment, the thermal conduction unit 10a further includes a protective layer 15 disposed between the first hollow part 111 and the first heat pipe 20, and a protective layer 16 disposed between the second hollow part 121 and the second heat pipe 40. In the embodiment, the second heat pipe 40 is thermally coupled to the heat source 30 though the second thermal conduction part 12, the rotation unit 17, the first conduction part 11 and the first heat pipe 20.

In the embodiment, the thermal hinge structure 1a further includes a first fixed part 13. The first fixed part 13 is connected to the first thermal conduction part 11 and embedded in the base plate 70, such as the base plate of laptop or mobile phone, so that the first thermal conduction part 11 is disposed adjacent to the side edge 71 of the base plate 70. In the embodiment, the first thermal conduction part 11, the first fixed part 13, the first heat pipe 20 (including the first horizontal section 21, the first bent section 22 and the first extended section 23) and the heat source 30 are fixed on the base plate 70 and will not rotate relative to the base plate 70. In the embodiment, the thermal hinge structure 1a further includes a second fixed part 14. The second fixed part 14 is connected to the second thermal conduction part 12 and embedded in the screen 80, such as the screen of laptop or mobile phone, so that the second fixed part 12 is disposed adjacent to a side edge 81 of the screen 80. In the embodiment, the second heat pipe 40 further includes a second horizontal section 41, a second bent section 42 and a second extended section 43. The second horizontal section 41 is embedded in the second hollow part 121 along the second axis C2, the second bent section 42 is connected between the second horizontal section 41 and the second extended section 43, and the second extended section 43 is thermally coupled to a heat sink 31. The second thermal conduction part 12, the second fixed part 14, the second heat pipe 40 and the heat sink 31 are fixed on the screen 80, which are allowed to rotate relative to the base plate 70 at the angle ranged from 0° to 360°.

In the embodiment, the rotation unit 17 is allowed to rotate relative to the thermal heat conduction part 11 around the first axis C1 as the center. The second thermal conduction part 12 is allowed to rotate around the second axis C2. The first axis C1 and the second axis C2 are parallel to each other. Thereby, the second thermal conduction part 12 is allowed to rotate relative to the first thermal conduction part 11. The rotation unit 17 provides functions of connection and mutual rotation between the first thermal conduction part 11 and the second thermal conduction part 12, thereby realizing the rotation of the screen 80 relative to the base plate 70 at the angle ranged from 0° to 360°. In an embodiment, the screen 80 is allowed to rotate to 0° relative to the base plate 70 through the first thermal conduction part 11, the rotation unit 17 and the second thermal conduction part 12, so that the screen 80 and the base plate 70 are closed and attached face to face. In another embodiment, the screen 80 is allowed to rotate to 360° relative to the base plate 70 through the first thermal conduction part 11, the rotation unit 17 and the second thermal conduction part 12, so that the screen 80 and the base plate 70 are fully expanded and attached back to back. In other embodiments, the rotation angle of the screen 80 relative to the base plate 70 is adjustable according to the practical requirements, without affecting the heat transfer effect between the second thermal conduction part 12 and the first thermal conduction part 11. In the embodiment, the first thermal conduction part 11 and the second thermal conduction part 12 are allowed to rotate with each other through the arrangement of the rotation unit 17, and the base plate 70 connected to the first thermal conduction part 11 and the screen 80 connected to the second thermal conduction part 12 can perform flipping movements from 0° to 360°. Certainly, the way in which the first thermal conduction part 11 and the second thermal conduction part 12 rotate with each other through the rotation unit 17 can also be adjusted according to the practical requirements, and the present disclosure is not limited thereto.

In the embodiment, the thermal hinge structure 1a further includes two structural support hinge structures 9. The two structural support hinge structures 9 are disposed outside two opposite ends of the thermal hinge structure 1a, respectively, so as to provide strong support for the opening and closing rotation of the screen 80 relative to the base plate 70. The thermal hinge structure 1a of the present disclosure is disposed between the two structural support hinge structures 9 to provide a high thermal conduction path between the base plate 70 (i.e., the heat source 30) and the screen 80. By designing the thermal hinge structure 1a and the structural support hinge structures 9 separately, the feasibility and the reliability of the thermal hinge structure 1a are improved. Certainly, the present disclosure is not limited thereto.

In the embodiment, the thermal conduction unit 10a is formed by a high thermal conductivity material, and the high thermal conductivity material includes copper, copper alloys, aluminum or aluminum alloys. Preferably but not exclusively, the high thermal conductivity material has a thermal conductively coefficient ranged from 200 W/m·K to 400 W/m·K. In the embodiment, the first heat pipe 20 include a capillary structure 200 disposed on an inner wall surface of the first heat pipe 20, and the second heat pipe 40 include a capillary structure 400 disposed on an inner wall surface of the second heat pipe 40. In the embodiment, the first bent section 22 of the first heat pipe 20 has an outer bent region 22a and an inner bent region 22b. Preferably but not exclusively, the outer bent region 22a is away from the heat source 30, and the inner bent region 22b is close to the heat source 30. In the embodiment, a density of the capillary structure in the inner bent region 22b is greater than a density of the capillary structure in the outer bent region 22a. Similarly, the second bent section 42 of the second heat pipe 40 has an outer bent region 42a and an inner bent region 42b. Preferably but not exclusively, the outer bent region 42a is away from the heat sink 31, and the inner bent region 42b is close to the heat sink 31. In the embodiment, a density of the capillary structure in the inner bent region 42b is greater than a density of the capillary structure in the outer bent region 42a. Thereby, the thermal hinge structure 1a of the present disclosure uses dual pivot shafts and dual heat pipes to form an optimized thermal conduction path. The thermal conductivity coefficient K of the thermal conduction unit 10a is greater than 200 W/m·K, and it ensures that the heat source 30 from the base plate 70 is effectively transferred to the heat sink 31 through the first heat pipe 20, the first thermal conduction part 11, the rotation unit 17, the second thermal conduction part 12, the second heat pipe 40. In that, the heat can be evenly distributed on the screen 80, and it allows the screen 80 to achieve an even temperature effect.

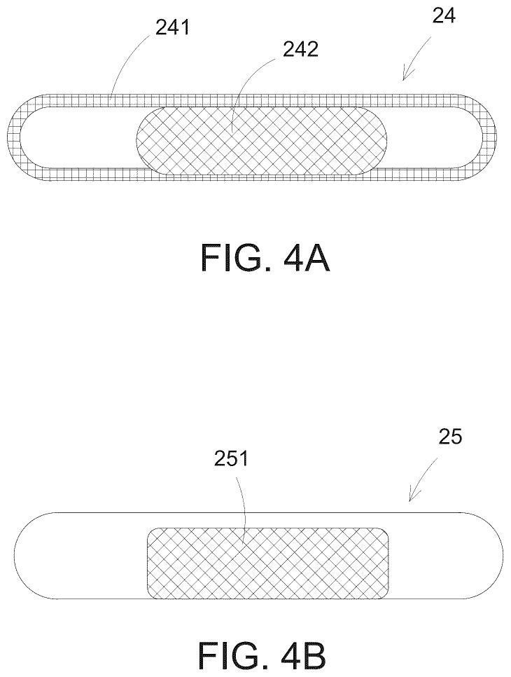

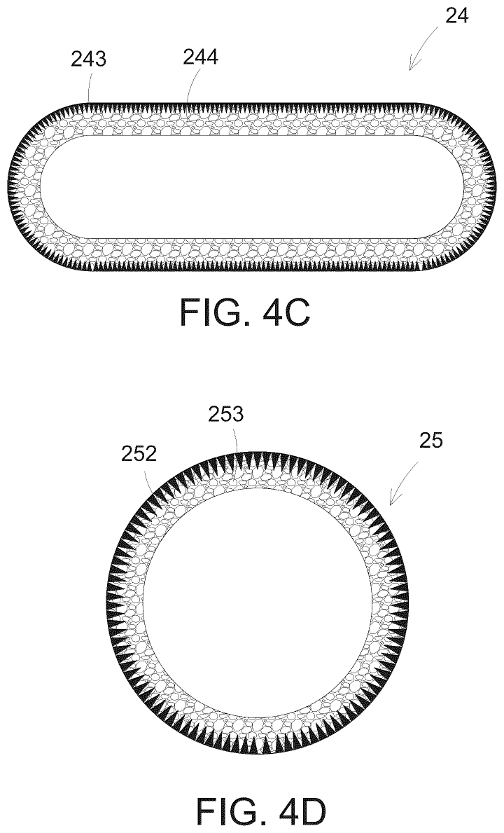

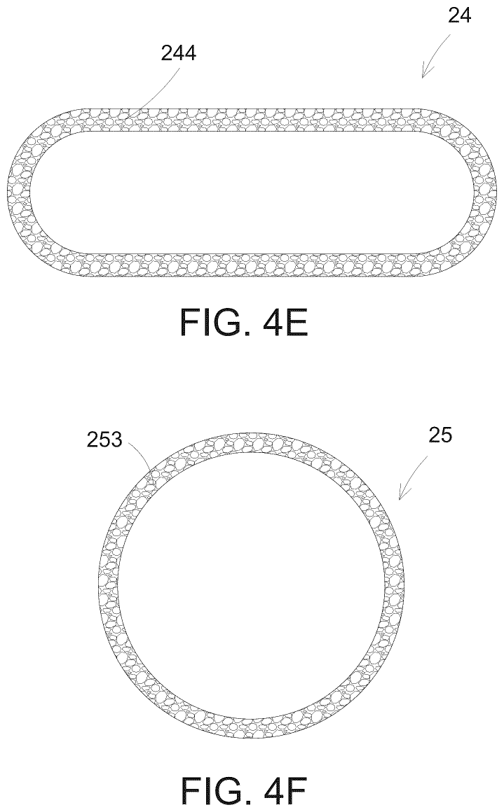

In the embodiment, the capillary structure 200 in the first heat pipe 20 and the capillary structure 400 in the second heat pipe 40 can be adjusted according to the location of the thermal conduction path. The place where the first heat pipe 20 contacts the heat source 30 can be defined as an evaporation end 24, and the place where the first heat pipe 20 contacts the first hollow part 111 of the first thermal conduction part 11 can be defined as a condenser end 25. In an embodiment, a cross section of the first heat pipe 20 at the evaporation end 24 is, for example, a flat oblong shape, and includes an internal microstructure, which is composed of meshes 241 and fibers 242 and placed in the center, as shown in FIG. 4A. In addition, a cross section of the first heat pipe 20 at the condensation end 25 is, for example, a flat oblong shape, and includes an internal microstructure, which is composed of fibers 251 and placed in the center, as shown in FIG. 4B. In another embodiment, a cross section of the first heat pipe 20 at the evaporation end 24 is, for example, a flat oblong shape, and includes an internal microstructure composed of grooves 243 and powder 244, as shown in FIG. 4C. In addition, a cross section of the first heat pipe 20 at the condensation end 25 is, for example, a circle, and includes an internal microstructure composed of grooves 252 and powders 253, as shown in FIG. 4D. In a further embodiment, a cross section of the first heat pipe 20 at the evaporation end 24 is, for example, a flat oblong shape, and includes an internal microstructure composed of powder 244, as shown in FIG. 4E. In addition, a cross section of the first heat pipe 20 at the condensation end 25 is, for example, a circle, and includes an internal microstructure composed of powders 253, as shown in FIG. 4F. In the embodiment, the evaporation end 44 and the condensation end 45 of the second heat pipe 40 can also change the internal microstructure similar to those in the first heat pipe 20 described above.

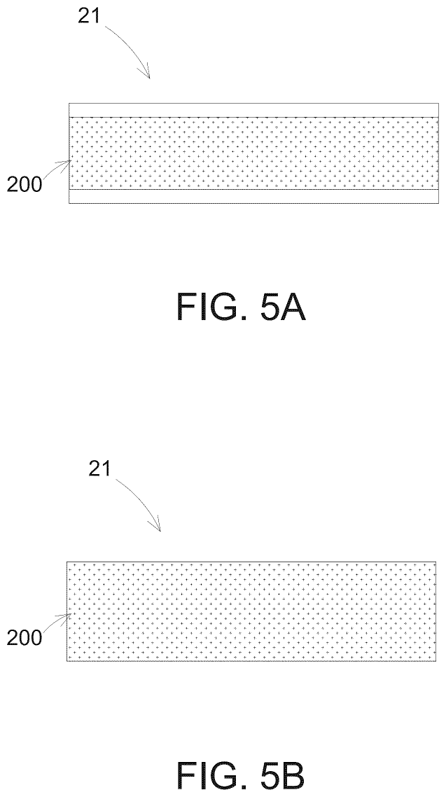

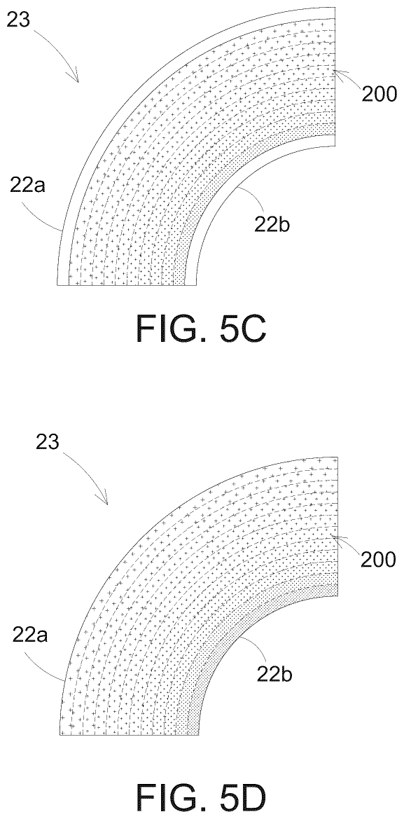

In addition, the capillary structure 200 in the first heat pipe 20 and the capillary structure 400 in the second heat pipe 40 can adjust the density thereof according to the position. FIGS. 5A to 5D are longitudinal sections illustrating density change of capillary structure of the heat pipe in the present disclosure. Please refer to FIG. 1 and FIGS. 5A to 5D. In the embodiment, the first heat pipe 20 is taken as an example, and the first horizontal section 21 or the first extended section 23 is in the shape of a straight tube, and includes the capillary structure 200 thereof evenly distributed. The capillary structure 200 is uniformly distributed and placed in the middle (as shown in FIG. 5A), or in a full-tube arrangement (as shown in FIG. 5B). In the embodiment, in the first bent section 22 of the first heat pipe 20, the density of the capillary structure in the inner bent region 22b is greater than the density of the capillary structure in the outer bent region 22a. The capillary structure 200 can be placed in the middle (as shown in FIG. 5C), or in a full-tube arrangement (as shown in FIG. 5D). Preferably but not exclusively, the capillary structure 200 in the first bent section 22 is formed by bending a straight tube. The density of the capillary structure in the inner bent region 22b after being bent is greater than that before being bent, so that the capillary force greater than that of the straight pipe is provided. Moreover, the inner path of the bent region 22b in first bent section 22 is squeezed and shortened. On the contrary, the density of the capillary structure in the outer bent region 22a after being bent is less than that before being bent, so that the capillary force smaller than that of the straight pipe is provided. The path of the outer bent region 22a is stretched and becomes longer. In the embodiment, the first bent section 22 is formed by bending the first heat pipe 20, and it will cause differences in capillary density and transporting path compared to the first horizontal section 21 or the first extended section 23 in the shape of the straight tube, so that the capillary performance is affected. Certainly, since the first extended section 23 and the first bent section 22 are served as the connection between the condensation end 25 and the evaporation end 24, the length, the quantity, the density of capillary structure are adjustable according to the practical requirements. Preferably but not exclusively, in the embodiment, the density of the capillary structure 200 in the first bent section 22 is decreased linearly from the inner bent region 22b to the outer bent region 22a, so as to control the overall performance of the capillary structure 200. In other embodiments, it allows to reduce the bent sections or avoid acute-angle bending in the first heat pipe 20 or the second heat pipe 40 for reducing changes in capillary performance. The present disclosure is not limited thereto.

Furthermore, notably, in the embodiment, the thermal hinge structure 1a includes dual pivot shafts combined with the heat pipes. The first thermal conduction part 11 is combined with the first heat pipe 20 and the second thermal conduction part 12 is combined with the second heat pipe 40 to form two thermal conduction pivot shafts parallel to each other. A spaced distance D is formed between the first heat pipe 20 and the second heat pipe 40, and the spaced distance D is maintained less than 15 mm. Preferably but not exclusively, an optimal thermal conduction path is provided between the first thermal conduction part 11 and the second thermal conduction part 12 through the rotation unit 17 of an integrated gear component. In the embodiment, when the spaced distance D between the first heat pipe 20 and the second heat pipe 40 is less than 15 mm, the temperature difference between the first thermal conduction part 11 and the second thermal conduction part 12 can be controlled to be less than 10° C. In the embodiment, the first fixed part 13 is cooperated with the first heat pipe 20, which is bent and fixed on the base plate 70 and thermally coupled to the heat source 30. Furthermore, the second fixed part 14 is cooperated with the second heat pipe 40, which is fixed to the screen 80 and configured to be thermally coupled to the heat sink 31. Preferably but not exclusively, the thermal hinge structure 1a is formed by a high thermal conductivity material, such as copper, copper alloys, aluminum or aluminum alloys. Thereby, a high thermal conduction path from the heat source 30 is formed through the first heat pipe 20, the first thermal conduction part 11, the rotation unit 17, the second thermal conduction part 12, the second heat pipe 40 and the screen 80. The temperature difference between the heat source 30 and the evaporation end 24 of the first heat pipe 20 is less than 5° C. The temperature difference between the evaporation end 24 of the first heat pipe 20 and the condensation end 25 of the first heat pipe 20 is less than 3° C. The temperature difference between the condensation end 25 of the first heat pipe 20 and the thermal conduction unit 10a is less than 3° C. The temperature difference from the first thermal conduction part 11 to the second thermal conduction par 12 is less than 10° C. The temperature difference from the second thermal conduction part 12 to the evaporation end 44 of the second heat pipe 40 is less than 3° C. The temperature difference between the evaporation end 44 of the second heat pipe 40 and the condensation end 45 of the second heat pipe 40 is less than 3° C. The temperature difference between the condensation end 45 of the second heat pipe 40 and the heat sink 31 is less than 5° C. In this way, the temperature difference between any two components can be maintained less than 10° C., thereby the overall passive heat dissipation effect of the system is improved sufficiently. Certainly, the present disclosure is not limited thereto, and not redundantly described hereafter.

In summary, the present disclosure provides a thermal hinge structure for improving the passive heat dissipation. The thermal hinge structure is combined with a heat pipe through at least one pivot shaft to reduce the thermal resistance and temperature difference from the keyboard end to the screen end, so that an optimized thermal conduction path is formed, and the heat dissipation performance of the product is improved greatly. The thermal hinge structure of the present disclosure can be combined with general hinges that provide structural support. The general hinges are placed on the left side and the right side of the notebook computers or mobile phones to provide strong support for opening or closing the screen. The thermal hinge structure can be placed between the general hinges, so that a high thermal conduction path is provided between the base plate (the heat source) and the screen. Furthermore, the thermal hinge structure of the present disclosure can also be installed independently to provide a high thermal conduction path between the base plate (the heat source) and the screen. The thermal hinge structure can use one single pivot shaft or dual pivot shafts combined with the heat pipes to form a thermal conduction unit. One fixed part at one end is cooperated with the heat pipe, which is bent and fixed on the base plate and thermally coupled to the heat source. Another fixed part at another end is cooperated with the heat pipe, which is fixed to the screen and configured to be thermally coupled to the heat sink. The fixed parts at both ends are connected by the thermal conduction unit to form a high thermal conduction path. The thermal conductivity coefficient K is greater than 200 W/m·K, and it ensures that the heat source from the base plate is effectively conducted through the heat pipe at the base plate, the thermal conduction unit, the heat pipe at the screen or other heat distribution components. In that, the heat can be evenly distributed on the screen, and it allows the screen to achieve an even temperature effect. On the other hand, the thermal hinge structure is designed separately from the general support hinge, so as to improve the feasibility and the reliability of the thermal hinge structure. The thermal conduction unit composed of heat pipes and high thermal conductivity materials can effectively transfer and distribute the “heat source” to hinge application products, so that the power consumption of the passive cooling system can be further increased (from 12 W to 18˜30 W). Furthermore, the thermal hinge structure of the present disclosure can effectively disperse the heat source of the base plate to the screen end. It allows to take advantage of the large screen area as a heat sink to further enhance the overall system power. The thermal hinge structure can be used in mobile phones, NB, tablets, folding screens and other products. The thermal hinge structure includes dual pivot shafts combined with heat pipes to form two parallel thermal conduction parts, and the spaced distance between each other is maintained within 15 mm. The fixed part connected to the first thermal conduction part is cooperated with the first heat pipe, and the first heat pipe is bent and fixed on the base plate and is thermally coupled to the heat source. The fixed part connected to the second thermal conduction part is fixed to the screen and cooperated with the second heat pipe, and the second heat pipe is thermally coupled to the heat sink. The first thermal conduction part and the second thermal conduction part are connected through a rotation unit, and the rotation unit allows to perform flipping movements from 0° to 360°. In addition, the thermal hinge structure is made of high thermal conductivity materials, such as copper, copper alloy, aluminum, and aluminum alloy. In this way, a high thermal conduction path from the heat source is formed through the first heat pipe, the thermal conduction unit, the second heat pipe and the screen, and the temperature difference between any two components can be maintained less than 10° C., thereby the overall passive heat dissipation effect of the system is improved sufficiently.

While the disclosure has been described in terms of what is presently considered to be the most practical and preferred embodiments, it is intended to cover various modifications and similar arrangements included within the spirit and scope of the appended claims which are to be accorded with the broadest interpretation so as to encompass all such modifications and similar structures.

What is claimed is:

1. A thermal hinge structure, comprising:
a thermal conduction unit comprising a first thermal conduction part and a second thermal conduction part, wherein the first thermal conduction part has a first hollow part, the first hollow part is arranged along a first axis, and the second thermal conduction part is configured to rotate relative to the first hollow part around the first axis as the center;
a first heat pipe comprising a horizontal section, a bent section and an extended section, wherein the horizontal section is disposed in the first hollow part, the bent section is connected between the horizontal section and the extended section, and the extended section is thermally coupled to a heat source; and
a second heat pipe disposed on the second thermal conduction part and thermally coupled to the heat source through the thermal conduction unit and the first heat pipe.

2. The thermal hinge structure according to claim 1, wherein the thermal conduction unit further comprises a protective layer disposed between the first hollow part and the first heat pipe.

3. The thermal hinge structure according to claim 1, wherein the first thermal conduction part is disposed on a side edge of a base plate, the extended section of the first heat pipe and the heat source are fixed on the base plate, the second thermal conduction part is connected to a screen, and the second thermal conduction part and the second heat pipe are fixed on the screen.

4. The thermal hinge structure according to claim 3, wherein the second thermal conduction part comprises a second hollow part, the second heat pipe further comprises a horizontal section, a bent section and an extended section, the bent section is connected between the horizontal section and the extended section, the horizontal section is embedded in the second hollow part, the extended section is thermally coupled to a heat sink, and the heat sink is disposed on the screen.

5. The thermal hinge structure according to claim 1, wherein the first heat pipe and the second heat pipe comprise a capillary structure, respectively, and the capillary structures are disposed on an inner wall surface of the first heat pipe and an inner wall surface of the second heat pipe.

6. The thermal hinge structure according to claim 5, wherein the bent section of the first heat pipe has an outer bent region and an inner bent region, and a density of the capillary structure in the inner bent region is greater than a density of the capillary structure in the outer bent region.

7. The thermal hinge structure according to claim 6, wherein the density of the capillary structure in the bent section is decreased linearly from the inner bent region to the outer bent region.

8. The thermal hinge structure according to claim 1, further comprising a first fixed part connected to the first thermal conduction part and embedded in a base plate, wherein the first thermal conduction part is disposed adjacent to a side edge of the base plate, and the first fixed part, the extended section of the first heat pipe and the heat source are fixed on the base plate.

9. The thermal hinge structure according to claim 8, further comprising a second fixed part, wherein the second fixed part is connected to the second thermal conduction part and embedded in a screen, and the second fixed part is disposed adjacent to a side edge of the screen, wherein the second thermal conduction part comprises a second hollow part, the second heat pipe further comprises a horizontal section, a bent section and an extended section, the bent section is connected between the horizontal section and the extended section, the horizontal section is embedded in the second hollow section, the extended section is thermally coupled to a heat sink, and the heat sink is disposed on the screen.

10. A thermal hinge structure, comprising:
a thermal conduction unit comprising a first thermal conduction part, a rotation unit and a second thermal conduction part, wherein the first thermal conduction part has a first hollow part, the first hollow part is arranged along a first axis, the second thermal conduction part is arranged along a second axis, the first axis and the second axis are parallel to each other, and the rotation unit is connected between the first thermal conduction part and the second thermal conduction part;
a first heat pipe comprising a horizontal section, a bent section and an extended section, wherein the horizontal section is disposed in the first hollow part, the bent section is connected between the horizontal section and the extended section, and the extended section is thermally coupled to a heat source; and
a second heat pipe disposed on the second thermal conduction part and thermally coupled to the heat source through the second thermal conduction part, the rotation unit, the first conduction part and the first heat pipe.

11. The thermal hinge structure according to claim 10, wherein a spaced distance is formed between the first heat pipe and the second heat pipe, and the spaced distance is less than 15 mm.

12. The thermal hinge structure according to claim 10, wherein the thermal conduction unit further comprises a protective layer disposed between the first hollow part and the first heat pipe.

13. The thermal hinge structure according to claim 10, further comprising a first fixed part connected to the first thermal conduction part and embedded in a base plate, wherein the first thermal conduction part is disposed adjacent to a side edge of the base plate, and the first fixed part, the extended section of the first heat pipe and the heat source are fixed on the base plate.

14. The thermal hinge structure according to claim 10, further comprising a second fixed part, wherein the second fixed part is connected to the second thermal conduction part and embedded in a screen, and the second fixed part is disposed adjacent to a side edge of the screen, wherein the second thermal conduction part comprises a second hollow part, the second heat pipe further comprises a horizontal section, a bent section and an extended section, the bent section is connected between the horizontal section and the extended section, the horizontal section is embedded in the second hollow section, the extended section is thermally coupled to a heat sink, and the heat sink is disposed on the screen.

15. The thermal hinge structure according to claim 10, wherein the rotation unit is a gear component, and the second thermal conduction part is allowed to rotate at an angle relative to the first thermal conduction part through the gear component, and the angle is ranged from 0° to 360°.

16. The thermal hinge structure according to claim 10, wherein the thermal conduction unit is formed by a high thermal conductivity material, and the high thermal conductivity material has a thermal conductively coefficient ranged from 200 W/m·K to 400 W/m·K.

17. The thermal hinge structure according to claim 10, further comprising a structural support hinge structure, wherein the structural support hinge structure is disposed outside two opposite ends of the thermal hinge structure.

18. The thermal hinge structure according to claim 10, wherein the first heat pipe and the second heat pipe comprise a capillary structure, respectively, and the capillary structures are disposed on an inner wall surface of the first heat pipe and an inner wall surface of the second heat pipe.

19. The thermal hinge structure according to claim 18, wherein the bent section of the first heat pipe has an outer bent region and an inner bent region, and a density of the capillary structure in the inner bent region is greater than a density of the capillary structure in the outer bent region.

20. The thermal hinge structure according to claim 19, wherein the density of the capillary structure in the bent section is decreased linearly from the inner bent region to the outer bent region.

21. The thermal hinge structure according to claim 11, wherein a temperature difference between the heat source and the first heat pipe, a temperature difference between the first heat pipe and the first thermal conduction part, and a temperature difference between the second thermal conduction part and the second heat pipe are less than 5° C.

22. The thermal hinge structure according to claim 11, wherein a cross section of the first heat pipe and a cross section of the second heat pipe are a circle or a flat oblong shape, and include an internal microstructure composed of meshes, fibers, grooves or sintered powders.
